(19) United States
(12) Patent Application Publication
(10) Pub. No.: US 2025/0311321 A1
(43) Pub. Date: Oct. 2, 2025

(54) SEMICONDUCTOR DEVICE AND METHOD OF FORMING THE SAME

(71) Applicant: YANGTZE MEMORY TECHNOLOGIES CO., LTD., Wuhan (CN)

(72) Inventors: Zongliang Huo, Wuhan (CN); Wei Xu, Wuhan (CN); Meng Wang, Wuhan (CN); Wenbin Zhou, Wuhan (CN); Beibei Li, Wuhan (CN); Bin Yuan, Wuhan (CN)

(21) Appl. No.: 18/671,501

(22) Filed: May 22, 2024

Related U.S. Application Data
(63) Continuation of application No. PCT/CN2024/084125, filed on Mar. 27, 2024.

(51) Int. Cl. H01L 29/06; H01L 29/66; H01L 29/78; H10B 12/00

(52) U.S. Cl. CPC H10D 62/115; H10B 12/50; H10D 30/63; H10D 64/017

(57) ABSTRACT

A semiconductor device includes a first gate structure and a second gate structure extending in a first direction and a second direction, a first isolation structure deposited between the first gate structure and the second gate structure extending in the first direction and the second direction, a first semiconductor structure deposited between the first gate structure and the first isolation structure extending in the first direction, a first contact structure deposited on the first semiconductor structure, a first dielectric layer deposited on the first gate structure, and a second dielectric layer deposited on the first isolation structure. A first center of the first end of the first contact structure in a third direction is perpendicular to the first direction. The second direction aligns with a second center of the first semiconductor structure in the third direction.

### CROSS-REFERENCE TO RELATED APPLICATIONS

This application is a continuation of International Application No. PCT/CN2024/084125, filed on Mar. 27, 2024, entitled “SEMICONDUCTOR DEVICE AND METHOD OF FORMING THE SAME,” which is incorporated herein by reference in its entirety.

### BACKGROUND

The present disclosure relates to semiconductor technology, and more particularly, to semiconductor devices and the method of forming semiconductor devices.

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

In one aspect, a semiconductor device is disclosed. The semiconductor device includes a first gate structure and a second gate structure extending in a first direction and a second direction perpendicular to the first direction, a first isolation structure deposited between the first gate structure and the second gate structure extending in the first direction and the second direction, a first semiconductor structure deposited between the first gate structure and the first isolation structure extending in the first direction, a first contact structure deposited on the first semiconductor structure, a first dielectric layer deposited on the first gate structure, and a second dielectric layer deposited on the first isolation structure. The first contact structure includes a first end in contact with the first semiconductor structure. A first center of the first end of the first contact structure in a third direction perpendicular to the first direction and the second direction aligns with a second center of the first semiconductor structure in the third direction.

In some implementations, the first center aligns with the second center in the first direction.

In some implementations, the first isolation structure includes an isolation core and a third dielectric layer between the isolation core and the first semiconductor structure.

In some implementations, the first isolation structure includes an air gap extending in the first direction.

In some implementations, the contact structure further includes a second end away from the semiconductor structure, and a first width of the first end in the third direction is greater than a second width of the second end in the third direction.

In some implementations, the semiconductor device further includes a second isolation structure, the first gate structure located between the first isolation structure and the second isolation structure, a second semiconductor structure deposited between the first gate structure and the second isolation structure, and a second contact structure deposited on the second semiconductor structure. Each of the first contact structure and the second contact structure includes a first inner edge close to the first gate structure and a first outer edge away from the first gate structure. Each of the first isolation structure and the second isolation structure includes a second inner edge close to the first gate structure and a second outer edge away from the first gate structure. A third center between the first outer edge of the first contact structure and the first outer edge of the second contact structure in the third direction aligns with a fourth center between the second inner edge of the first isolation structure and the second inner edge of the second isolation structure in the third direction.

In some implementations, the third center aligns with the fourth center along the first direction.

In some implementations, the semiconductor device further includes a storage structure coupled with the semiconductor structure through the contact structure.

In another aspect, a semiconductor device is disclosed. The semiconductor device includes a first isolation structure and a second isolation structure extending in a first direction and a second direction perpendicular to the first direction, a gate structure deposited between the first isolation structure and the second isolation structure extending in the first direction and the second direction, a first semiconductor structure deposited between the gate structure and the first isolation structure extending in the first direction, a second semiconductor structure deposited between the gate structure and the second isolation structure extending in the first direction, a first contact structure deposited on the first semiconductor structure, the first contact structure comprising a first inner edge close to the gate structure and a first outer edge away from the gate structure, and a second contact structure deposited on the second semiconductor structure, the second contact structure comprising a second inner edge close to the gate structure and a second outer edge away from the gate structure. The first isolation structure includes a first isolation core and a first dielectric layer between the first isolation core and the first semiconductor structure. The second isolation structure comprises a second isolation core and a second dielectric layer between the second isolation core and the second semiconductor structure. A first distance between the first outer edge of the first contact structure and an edge of the first dielectric layer in a third direction perpendicular to the first direction and the second direction is equal to a second distance between the second outer edge of the second contact structure and an edge of the second dielectric layer in the third direction.

In some implementations, each of the first isolation structure and the second isolation structure includes an air gap extending in the first direction.

In some implementations, the semiconductor device further includes a second dielectric layer deposited on the gate structure, and a third dielectric layer deposited on the first isolation structure. A width of the second dielectric layer in the third direction is different from a width of the third dielectric layer in the third direction.

In some implementations, the semiconductor device further includes a storage structure coupled with the semiconductor structure through the contact structure.

In still another aspect, a method is disclosed. A first mask layer is formed having a first opening on a semiconductor body. A second opening is formed in the semiconductor body extending in a first direction and a second direction perpendicular to the first direction. A gate structure is formed in the second opening. A portion of the first mask layer is removed to form a second mask layer. A portion of the semiconductor body is removed based on the second mask layer to form a semiconductor structure. A first dielectric layer is formed on the gate structure. The second mask layer is removed to form a third opening. A contact structure is formed in the third opening.

In some implementations, the semiconductor structure aligns with the contact structure in a third direction perpendicular to the first direction and the second direction.

In some implementations, a portion of the semiconductor body under the first opening is removed to form the second opening.

In some implementations, a gate dielectric layer is formed in the second opening, and a gate electrode layer is formed on the gate dielectric layer.

In some implementations, after forming the gate structure in the second opening, a sacrificial layer is formed in the first opening.

In some implementations, a first portion of the first mask layer is removed, and a second portion of the first mask layer aside from the sacrificial layer is retained to form the second mask layer.

In some implementations, the sacrificial layer is removed to form a fourth opening in the second mask layer.

In some implementations, the first dielectric layer is formed in the fourth opening.

In some implementations, the second mask layer on the semiconductor body is removed to expose the semiconductor body.

In some implementations, the contact structure is formed on the exposed semiconductor body.

In some implementations, a fifth opening is formed in the semiconductor body between two gate structures, and an isolation structure is formed in the fifth opening.

In some implementations, a portion of the semiconductor body is removed based on the second mask layer to form the fifth opening.

In some implementations, a second dielectric layer is formed on the semiconductor body and a third dielectric layer is formed on the second dielectric layer, and a portion of the second dielectric layer and the third dielectric layer is removed to form the first opening.

In some implementations, a first portion of the third dielectric layer is removed, and a second portion of the third dielectric layer aside from the sacrificial layer is retained, and a first portion of the second dielectric layer is removed, and a second portion of the second dielectric layer under the second portion of the third dielectric layer is retained.

In some implementations, the sacrificial layer and the second portion of the third dielectric layer are removed to form a sixth opening in the second mask layer to expose the gate structure.

In some implementations, the first dielectric layer is formed in the sixth opening.

In some implementations, the second portion of the second dielectric layer on the semiconductor body is removed to expose the semiconductor body.

In some implementations, the contact structure is formed on the exposed semiconductor body.

### BRIEF DESCRIPTION OF THE DRAWINGS

The accompanying drawings, which are incorporated herein and form a part of the specification, illustrate implementations of the present disclosure and, together with the description, further serve to explain the present disclosure and to enable a person skilled in the pertinent art to make and use the present disclosure.

FIG. 1 illustrates a schematic circuit diagram of an exemplary memory device, according to some implementations of the present disclosure.

FIG. 2 illustrates a schematic plan view of an exemplary memory device, according to some implementations of the present disclosure.

FIG. 3 illustrates a cross-sectional view of an exemplary memory device, according to some implementations of the present disclosure.

FIG. 4 illustrates a cross-sectional view of an exemplary memory device, according to some implementations of the present disclosure.

FIG. 5 illustrates a cross-sectional view of an exemplary memory device, according to some implementations of the present disclosure.

FIG. 6 illustrates a cross-sectional view of an exemplary memory device, according to some implementations of the present disclosure.

FIGS. 7-12 illustrate cross-sectional views of an exemplary memory device at various stages of a fabrication process, according to some implementations of the present disclosure.

FIG. 13 illustrates a flowchart of a method for forming a memory device, according to some implementations of the present disclosure.

FIGS. 14-18 illustrate cross-sectional views of an exemplary memory device at various stages of a fabrication process, according to some implementations of the present disclosure.

FIGS. 19-24 illustrate cross-sectional views of an exemplary memory device at various stages of a fabrication process, according to some implementations of the present disclosure.

FIG. 25 illustrates a block diagram of a system having a memory device, according to some implementations of the present disclosure.

Implementations of the present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “3D memory device” refers to a semiconductor device with vertically oriented strings of memory cell transistors (referred to herein as “memory strings,” such as NAND memory strings) on a laterally-oriented substrate so that the memory strings extend in the vertical direction with respect to the substrate. As used herein, the term “vertical/vertically” means perpendicular to the lateral surface of a substrate.

Transistors are used as the switch or selecting devices in the memory cells of some memory devices, such as dynamic radon access memory (DRAM). In a one-transistor-one-capacitor (1T1C) DRAM structure, the data are stored in the capacitors. There is a high requirement on the leakage issue of the selection transistors. Thus, it is necessary to identify alternative channel materials with a lower leakage compared to using monocrystalline silicon as the channel material. Moreover, with the continuous scaling development of DRAM, the unit size of a 1T1C cell continues to decrease, thereby increasing the influence of the leakage issue of the selection transistors. Further, the etching aspect ratio of the capacitors increases, causing serious challenges in the fabricating processes and increased product cost.

To address one or more of the aforementioned issues, the present disclosure introduces a solution with respect to the vertical transistors in a memory cell array of memory devices (e.g., DRAM). In the disclosed memory devices, low-leakage materials, such as a metal oxide semiconductor material, are selected to be used as the channel of the select transistors to solve the leakage problem in the process of DRAM scaling. By using a hard mask to form a protection layer during the word line formation process, a portion of the hard mask could be retained as the self-alignment mask in the later trench formation process, and therefore, the fabricating process can have a simplified source node contact (SNC) process, thereby reducing the product cost and increasing the reliability.

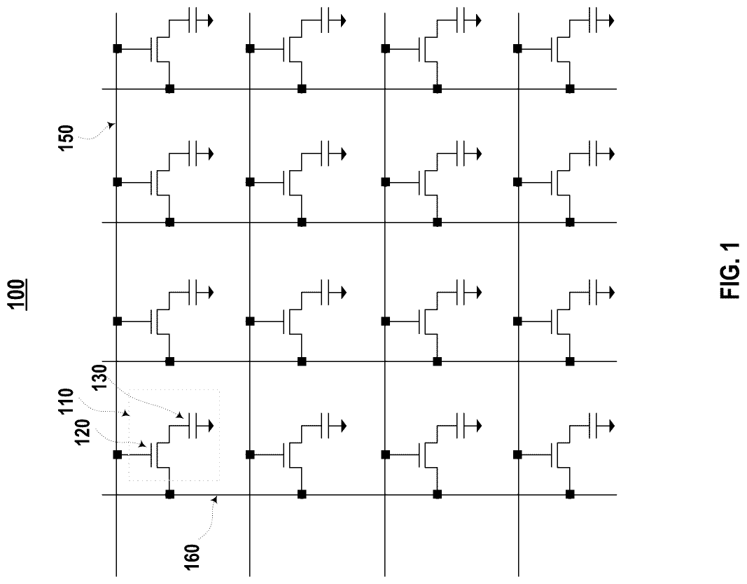

FIG. 1 illustrates a schematic circuit diagram of a memory device 100, according to some implementations of the present disclosure. Memory device 100 may include a memory cell array in which each memory cell 110 includes a vertical transistor 120 and a storage unit coupled to vertical transistor 120. In some implementations, as shown in FIG. 1, the memory cell array is a DRAM cell array, and the storage unit is a capacitor 130 for storing charge as the binary information stored by the respective DRAM cell. In some other implementations not shown in the figures, the memory cell array is a phase-change material (PCM) cell array, and the storage unit can be a PCM element (e.g., including chalcogenide alloys) for storing binary information of the respective PCM cell based on the different resistivities of the PCM element in the amorphous phase and the crystalline phase.

As shown in FIG. 1, memory cells 110 may be arranged in a two-dimensional (2D) array having rows and columns. Memory device 100 may include word lines 150 coupling the memory cell array to peripheral circuits for controlling the switch of vertical transistors 120 in memory cells 110 located in a row, as well as bit lines 160 coupling the memory cell array to peripheral circuits for sending data to and/or receiving data from memory cells 110 located in a column. That is, each word line 150 is coupled to a respective row of memory cells 110, and each bit line 160 is coupled to one or more respective logic columns of memory cells 110. In some implementations, the gate of vertical transistor 120 is coupled to word line 150, one of the source and the drain of vertical transistor 120 is coupled to bit line 160, the other one of the source and the drain of vertical transistor 120 is coupled to one electrode of capacitor 130, and the other electrode of capacitor 130 is coupled to the ground.

Consistent with the scope of the present disclosure, vertical transistors 120, such as vertical metal-oxide-semiconductor field-effect transistors (MOSFETs), can replace the conventional planar transistors as the pass transistors of memory cells 110 to reduce the area occupied by the pass transistors, the coupling capacitance, as well as the interconnect routing complexity, as described below in detail.

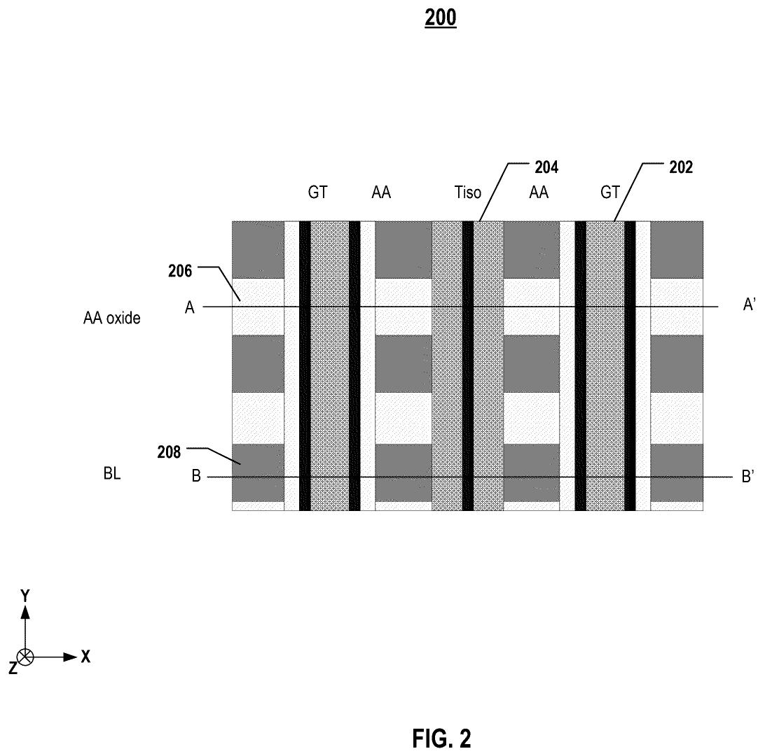

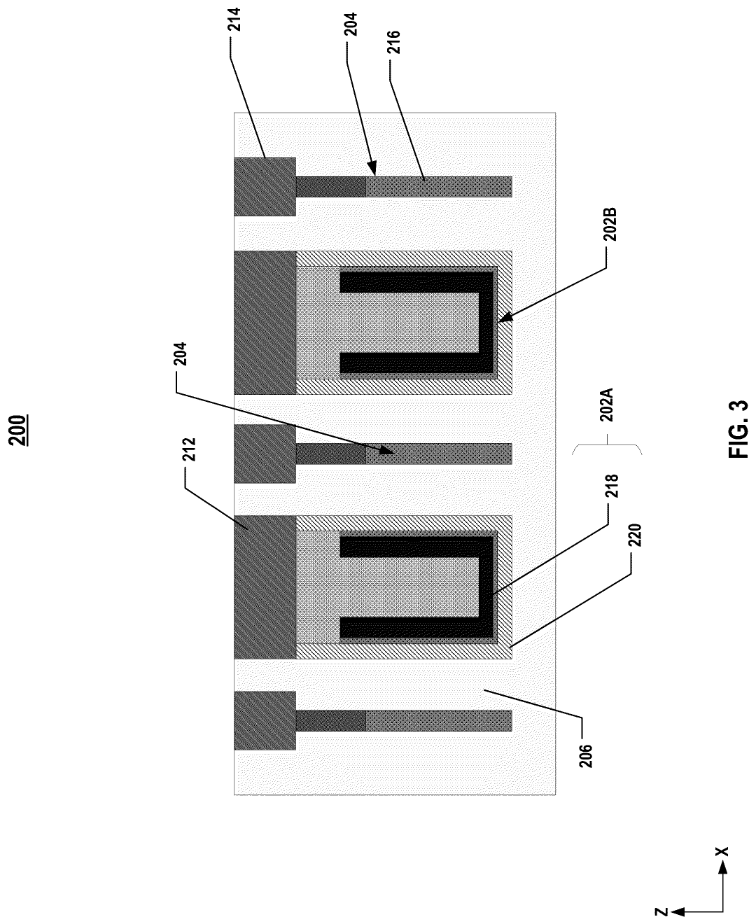

FIG. 2 illustrates a schematic plan view of a memory device 200, according to some implementations of the present disclosure. FIG. 3 illustrates a cross-sectional view of memory device 200 along line AA′ in FIG. 2, according to some implementations of the present disclosure. For the purpose of better describing the present disclosure, the plane view of memory device 200 in FIG. 2 and the cross-sectional view of memory device 200 in FIG. 3 will be discussed together.

As shown in FIG. 2, line AA′ is cut through a dielectric material 206, an isolation structure 204, and a gate structure 202, and line BB′ is cut through a semiconductor structure 208, isolation structure 204, and gate structure 202. As shown in FIG. 3, a first gate structure 220A and a second gate structure 220B are separated by isolation structure 204 and dielectric material 206. In some implementations, first gate structure 220A may be covered by a first dielectric layer 212 and isolation structure 204 may be covered by a second dielectric layer 214. In some implementations, first gate structure 220A may include a conductive layer 218 and a gate dielectric layer 220. In some implementations, conductive layer 218 may include tungsten (W), aluminum (Al), or other suitable material. In some implementations, gate dielectric layer 220 can include any suitable dielectric materials, such as silicon oxide, silicon nitride, silicon oxynitride, or high-k dielectrics. For example, gate dielectric layer 220 may include silicon oxide, i.e., gate oxide. In some implementations, isolation structure 204 may be formed by an isolation core 216.

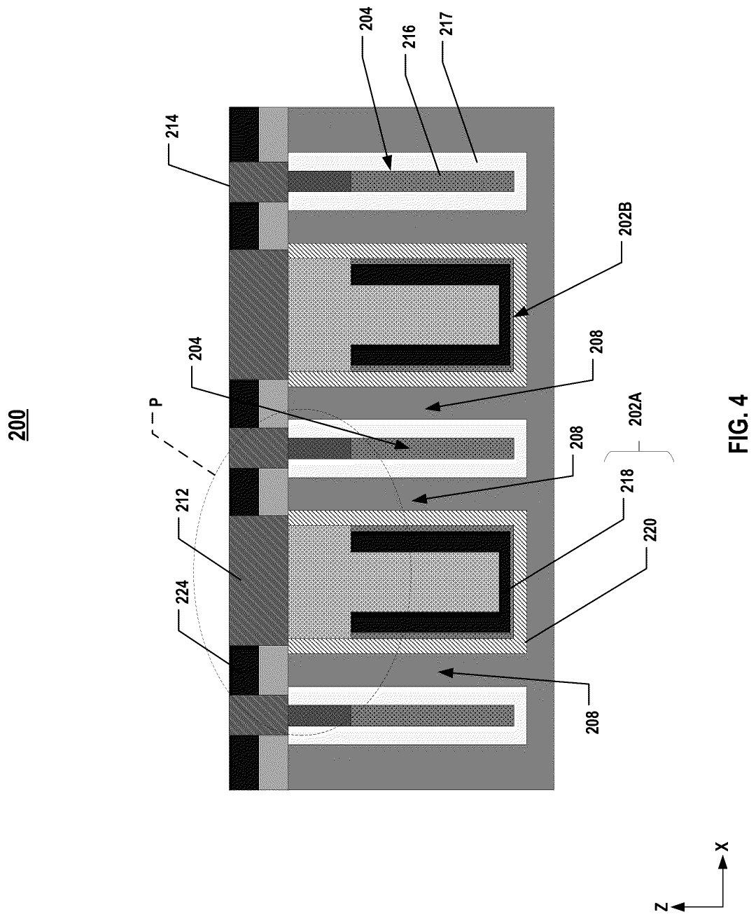

FIG. 4 illustrates a cross-sectional view of memory device 200 along line BB′ in FIG. 2, according to some implementations of the present disclosure. For the purpose of better describing the present disclosure, the plane view of memory device 200 in FIG. 2 and the cross-sectional view of memory device 200 in FIG. 4 will be discussed together.

As shown in FIG. 2 and FIG. 4, memory device 200 includes first gate structure 202A and second gate structure 202B extending in the Z-direction and the Y-direction. It is understood that the X-direction, the Y-direction, and the Z-direction are perpendicular to each other. Isolation structure 204 is deposited between first gate structure 202A and second gate structure 202B, and isolation structure 204 extends in the Z-direction and the Y-direction. Semiconductor structure 208 is deposited between first gate structure 202A and isolation structure 204 and is also deposited between second gate structure 202B and isolation structure 204. A contact structure 224 is deposited on semiconductor structure 208. First dielectric layer 212 is deposited on first gate structure 202A and second gate structure 202B and second dielectric layer 214 is deposited on isolation structure 204.

In some implementations, each of first gate structure 220A and second gate structure 220B may include conductive layer 218 and gate dielectric layer 220. In some implementations, conductive layer 218 may include tungsten (W), aluminum (Al), or other suitable material. In some implementations, conductive layer 218 may include multiple conductive layers, such as a W layer over a TiN layer. In some implementations, gate dielectric layer 220 is laterally between conductive layer 218 and semiconductor structure 208. In some implementations, gate dielectric layer 220 may include any suitable dielectric materials, such as silicon oxide, silicon nitride, silicon oxynitride, or high-k dielectrics. For example, gate dielectric layer 220 may include silicon oxide, i.e., gate oxide. In some implementations, isolation structure 204 may be formed by isolation core 216 covered by a dielectric layer 217. In some implementations, isolation structure 204 may be formed by an air gap extending in the Z-direction. In some implementations, a storage structure, e.g., capacitor 130, may be coupled with semiconductor structure 208 through contact structure 224.

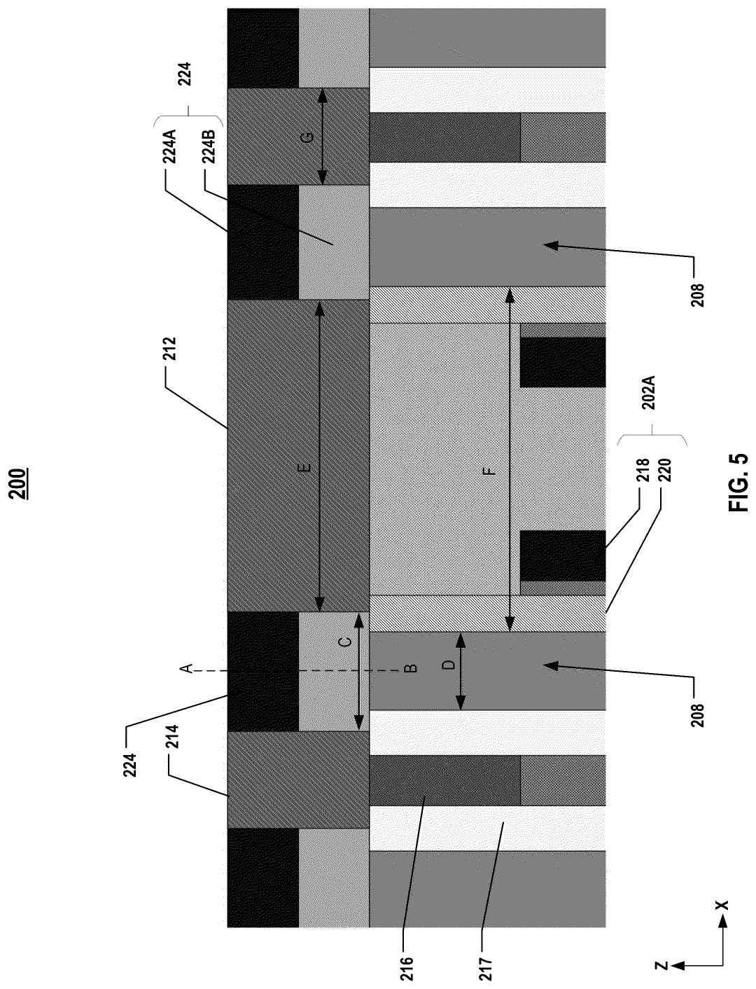

FIG. 5 illustrates an enlarged cross-sectional view of the portion P of memory device 200 shown in FIG. 4, according to some implementations of the present disclosure. As shown in FIG. 5, a center A of contact structure 224 in the X-direction aligns with a center B of semiconductor structure 208 in the X-direction along the Z-direction. In other words, the center A of contact structure 224 in the X-direction and the center B of semiconductor structure 208 in the X-direction overlap in the plan view of memory device 200. In some implementations, a first width C of contact structure 224 in the X-direction is greater than a second width D of semiconductor structure 208 in the X-direction. In some implementations, the first width C of contact structure 224 in the X-direction is equal to second width D of semiconductor structure 208 in the X-direction.

In some implementations, a third width E of first dielectric layer 212 in the X-direction is equal to a fourth width F of gate structure 202 in the X-direction. In some implementations, the third width E of first dielectric layer 212 in the X-direction is less than the fourth width F of gate structure 202 in the X-direction. In some implementations, the third width E of first dielectric layer 212 in the X-direction is different from a fifth width G of second dielectric layer 214 in the X-direction. In some implementations, the third width E of first dielectric layer 212 in the X-direction is greater than the fifth width G of second dielectric layer 214 in the X-direction.

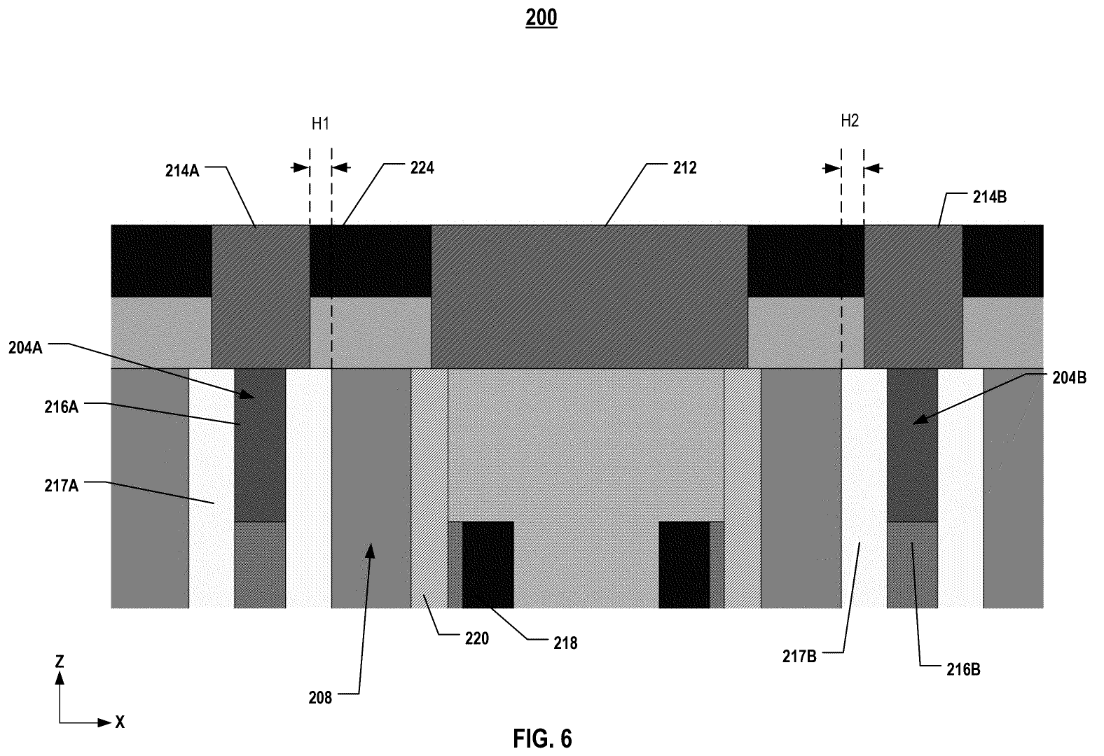

FIG. 6 illustrates an enlarged cross-sectional view of the portion P of memory device 200 shown in FIG. 4, according to some implementations of the present disclosure. As shown in FIG. 6, a first isolation structure 204A is formed by an isolation core 216A covered by a dielectric layer 217A, and a second isolation structure 204B is formed by an isolation core 216B covered by a dielectric layer 217B. Second dielectric layer 214 (214A/214B) is formed on first isolation structure 204A and second isolation structure 204B. A distance H1 is formed between the edge of dielectric layer 214A and the edge of dielectric layer 217A in the X-direction, and a distance H2 is formed between the edge of dielectric layer 214B and the edge of dielectric layer 217B in the X-direction. In some implementations, the distance H1 is equal to the distance H2.

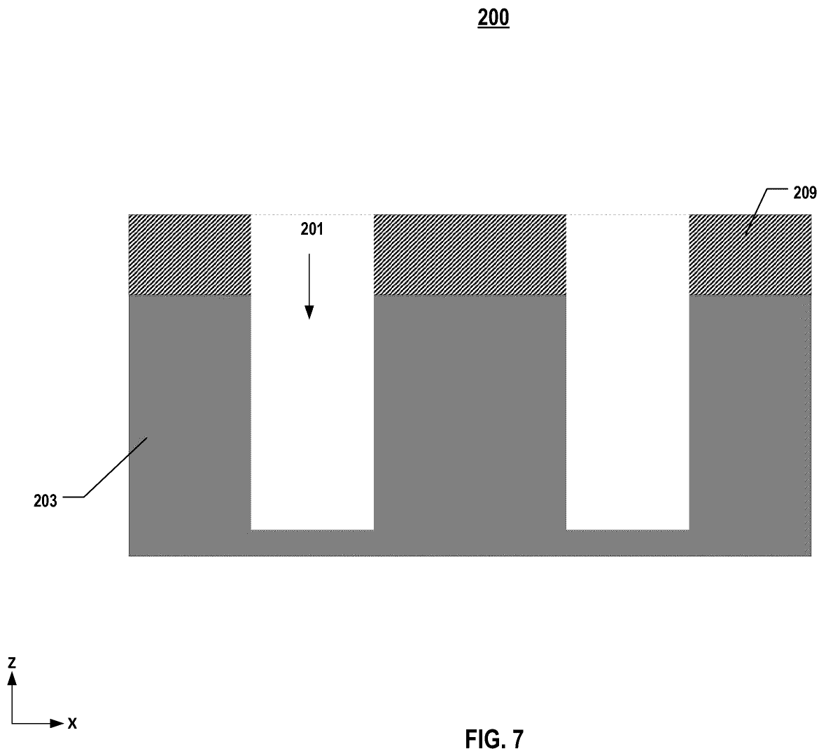

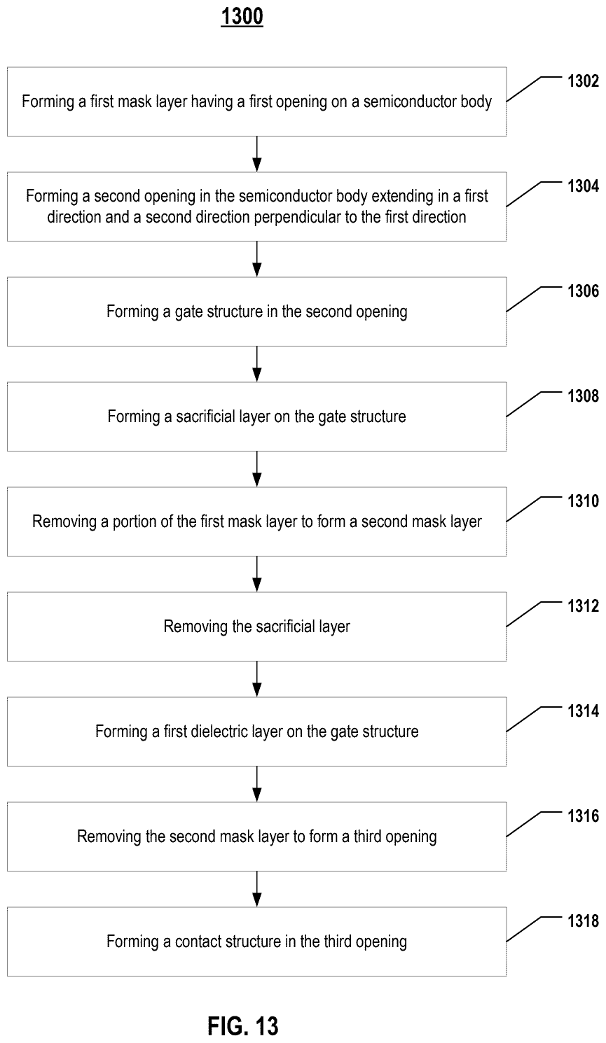

FIGS. 7-12 illustrate cross-sectional views of memory device 200 cut along line BB′ in FIG. 2 at various stages of a fabrication process, according to some implementations of the present disclosure. FIG. 13 illustrates a flowchart of a method 1300 for forming memory device 200, according to some implementations of the present disclosure. For the purpose of better describing the present disclosure, the memory device 200 in FIGS. 7-12 and method 1300 in FIG. 13 will be discussed together. It is understood that the operations shown in method 1300 are not exhaustive and that other operations may be performed as well before, after, or between any of the illustrated operations. Further, some of the operations may be performed simultaneously, or in a different order than shown in FIGS. 7-12 and FIG. 13.

As shown in FIG. 7 and the operation 1302 in FIG. 13, a first mask layer 209 is formed on a semiconductor body 203. In some implementations, first mask layer 209 may be a hard mask. In some implementations, first mask layer 209 may be a silicon nitride (SiN) layer. In some implementations, semiconductor body 203 may be a silicon substrate. Then, first mask layer 209 is patterned to form an opening on semiconductor body 203. Then, as shown in FIG. 7 and operation 1304 in FIG. 13, an opening 201 is formed in semiconductor body 203 using first mask layer 209 as a mask. In some implementations, opening 201 extends in the Z-direction and the Y-direction. In some implementations, opening 201 may be formed by using dry etching process, wet etching process, or any suitable removal process.

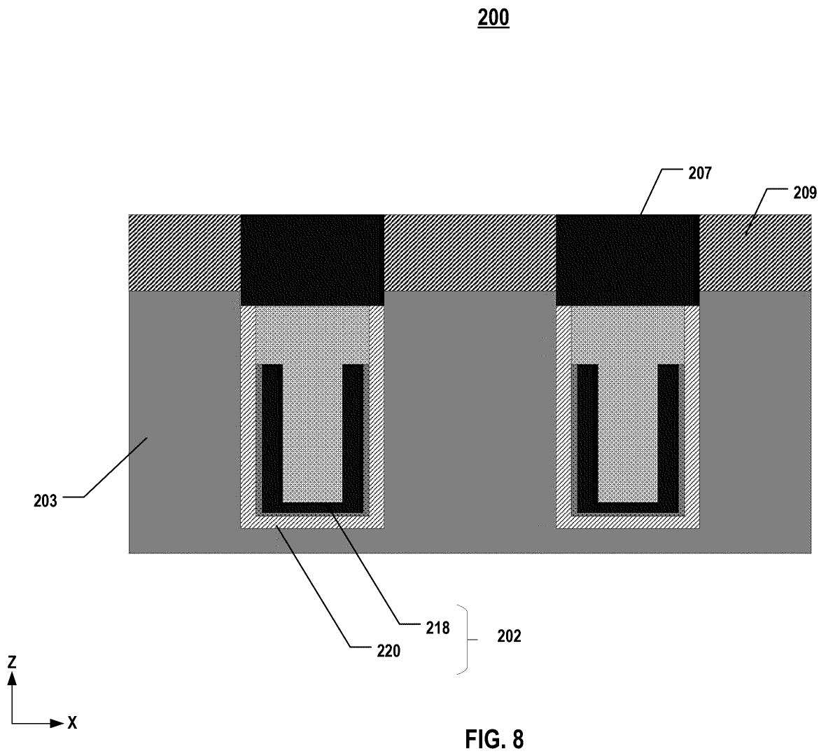

As shown in FIG. 8 and the operation 1306 in FIG. 13, gate structure 202 is formed in opening 201. In some implementations, gate structure 202 may include conductive layer 218 and gate dielectric layer 220. In some implementations, gate dielectric layer 220 is formed on the sidewalls of opening 201, and conductive layer 218 is formed on gate dielectric layer 220. In some implementations, conductive layer 218 may include tungsten (W), aluminum (Al), or other suitable material. In some implementations, conductive layer 218 may include multiple conductive layers, such as a W layer over a TiN layer. In some implementations, gate dielectric layer 220 can include any suitable dielectric materials, such as silicon oxide, silicon nitride, silicon oxynitride, or high-k dielectrics. For example, gate dielectric layer 220 may include silicon oxide, i.e., gate oxide. In some implementations, gate structure 202 extends in the Z-direction and the Y-direction.

As shown in FIG. 8 and operation 1308 in FIG. 13, a sacrificial layer 207 is formed on gate structure 202. In some implementations, sacrificial layer 207 is formed in opening 201. In some implementations, sacrificial layer 207 may be a material suitable to be removed in a later operation. In some implementations, sacrificial layer 207 may be a tungsten (W) layer.

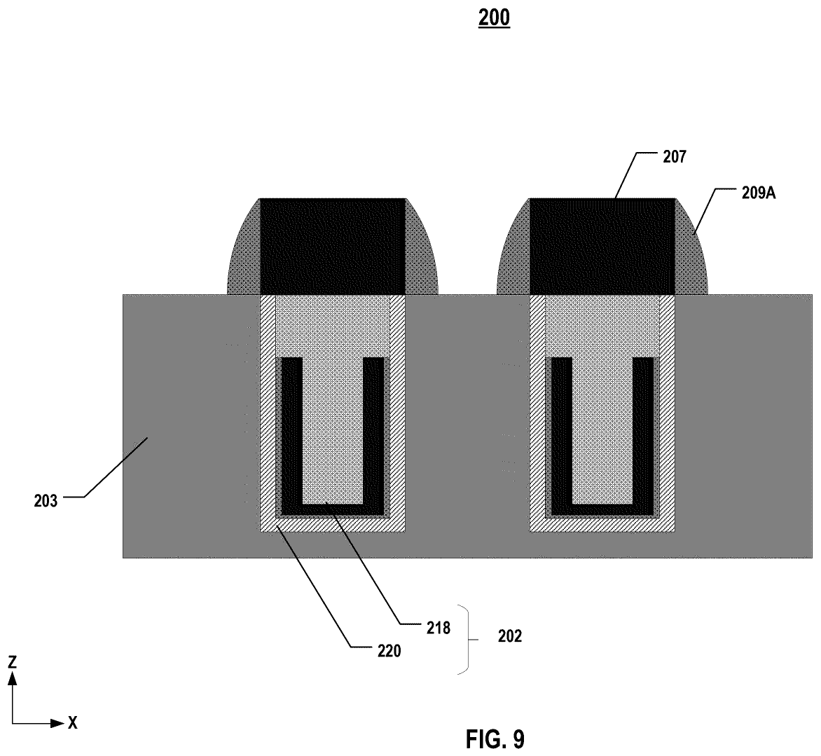

As shown in FIG. 9 and the operation 1310 in FIG. 13, a portion of first mask layer 209 is removed to form a second mask layer 209A. In some implementations, a first portion of first mask layer 209 is removed, and a second portion of first mask layer 209 aside from sacrificial layer 207 is retained to form second mask layer 209A. In some implementations, first mask layer 209 may be removed by using dry etching process, wet etching process, or any suitable removal process.

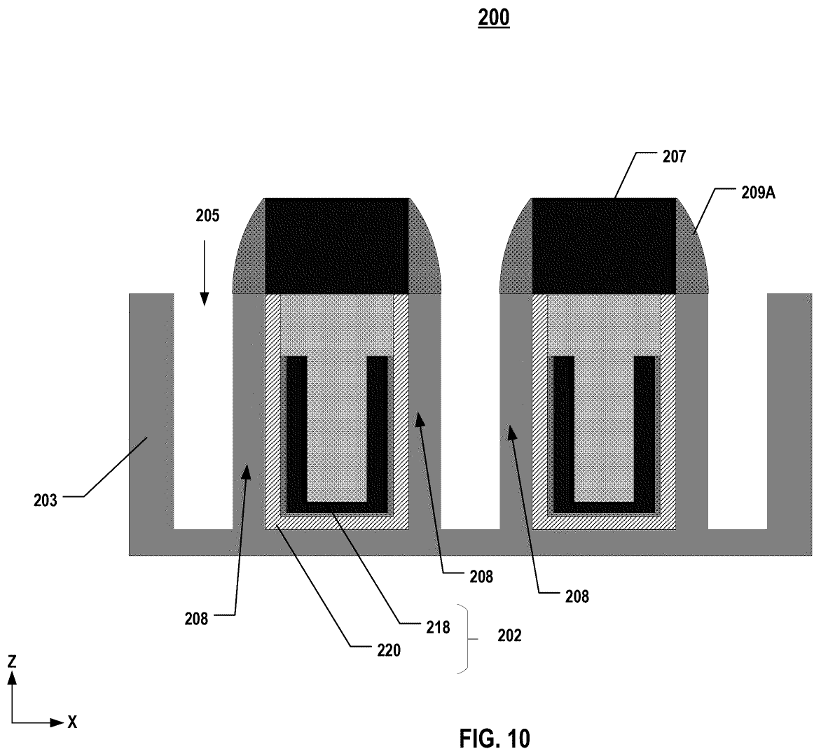

As shown in FIG. 10, an opening 205 is formed in semiconductor body 203. In some implementations, opening 205 extends in the Z-direction and the Y-direction. In some implementations, sacrificial layer 207 and second mask layer 209A may be used as a mask when forming opening 205. In some implementations, the edge of opening 205 aligns with the edge of second mask layer 209A in the Z-direction. After forming opening 205, semiconductor structure 208 is formed between opening 205 and gate structure 202. In some implementations, semiconductor structure 208 includes the same material as semiconductor body 203. In some implementations, semiconductor structure 208 extends in the Z-direction.

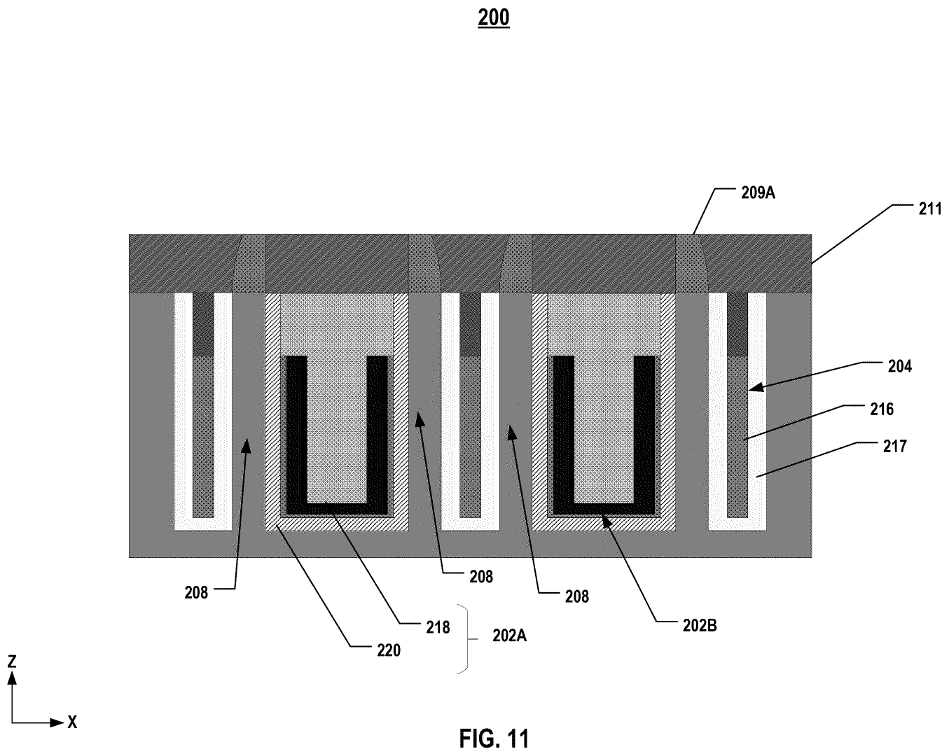

As shown in FIG. 11 and the operation 1312 in FIG. 13, isolation structure 204 is formed in opening 205, and sacrificial layer 207 is removed. In some implementations, isolation structure 204 may be formed by isolation core 216 covered by a dielectric layer 217. In some implementations, isolation structure 204 may be formed by forming an air gap in a dielectric material extending in the Z-direction. In some implementations, sacrificial layer 207 may be removed by using dry etching process, wet etching process, or any suitable removal process.

As shown in FIG. 11 and the operation 1314 in FIG. 13, after removing sacrificial layer 207, a dielectric layer 211 may be formed on gate structure 202 and isolation structure 204 aside second mask layer 209A. In some implementations, sacrificial layer 207 is removed to form an opening, and dielectric layer 211 is formed in the opening. In some implementations, dielectric layer 211 includes silicon oxide or silicon nitride.

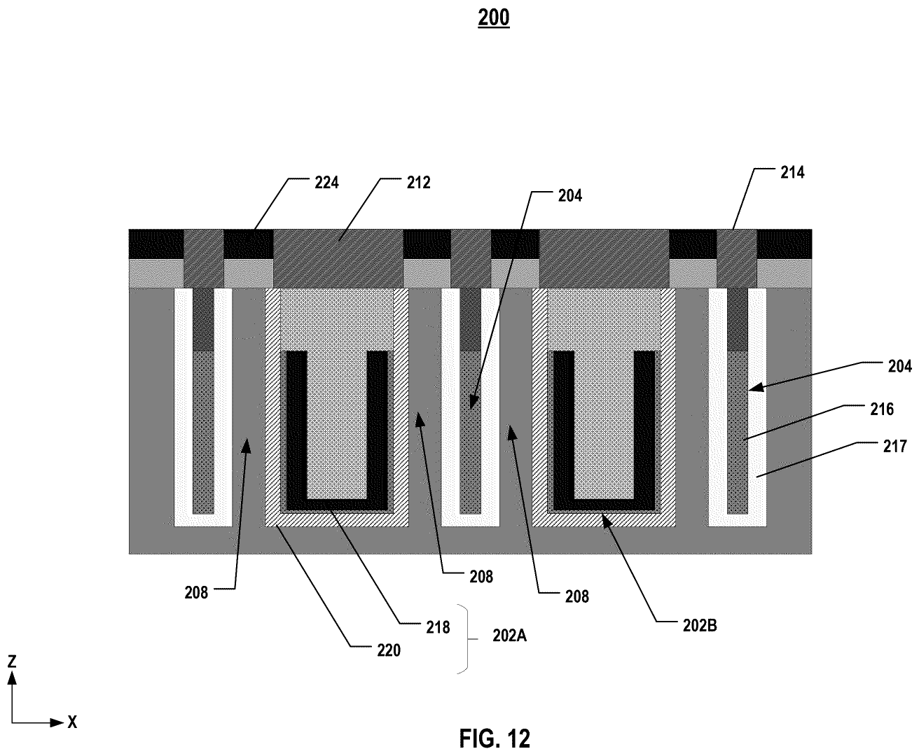

As shown in FIG. 12 and the operation 1316 in FIG. 13, second mask layer 209A is removed to form an opening. In some implementations, second mask layer 209A is removed to expose semiconductor structure 208. Then, as shown in FIG. 12 and operation 1318 in FIG. 13, contact structure 224 is formed in the opening. In some implementations, contact structure 224 is formed on the exposed semiconductor structure 208.

By using a hard mask, e.g., second mask layer 209A, to form a protection layer during the word line formation process, a portion of the hard mask could be retained as the self-alignment mask in the later trench formation process, e.g., opening 205 formation process. Hence, the contact, e.g., contact structure 224, can align with semiconductor structure 208, and the shifting problem can be prevented. The fabricating process can have a simplified source node contact (SNC) process, thereby reducing the product cost and increasing reliability.

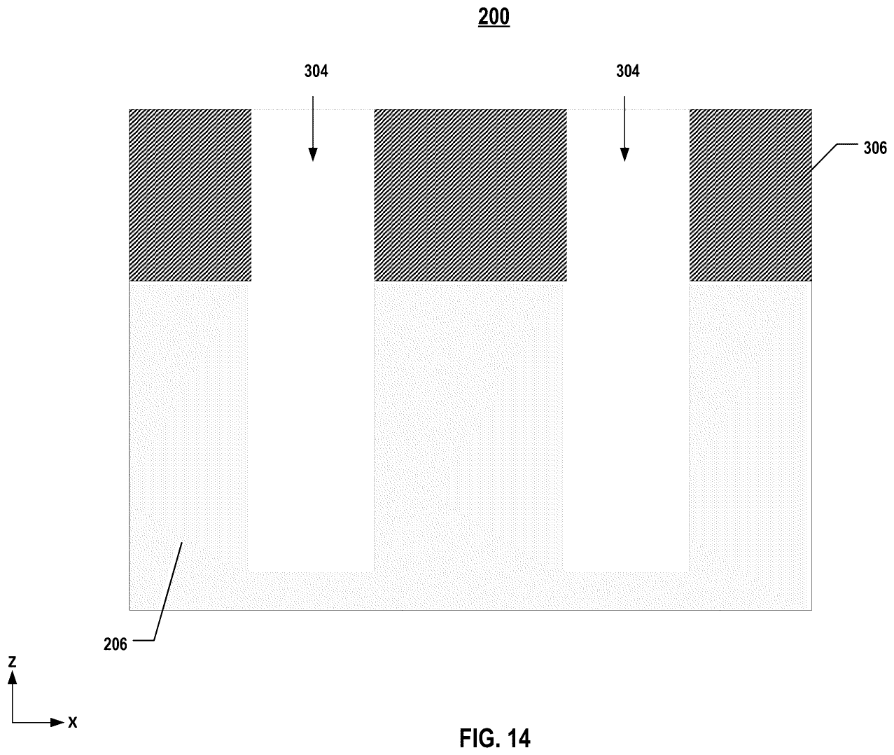

FIGS. 14-18 illustrate cross-sectional views of memory device 200 cut along line AA′ in FIG. 2 at various stages of a fabrication process, according to some implementations of the present disclosure.

As shown in FIG. 14, a mask layer 306 is formed on dielectric material 206. In some implementations, mask layer 306 may be a hard mask. In some implementations, mask layer 306 may be a silicon nitride (SiN) layer. In some implementations, dielectric material 206 may be a silicon oxide layer. Then, mask layer 306 is patterned to form an opening on dielectric material 206, and an opening 304 is formed in dielectric material 206 using mask layer 306 as a mask.

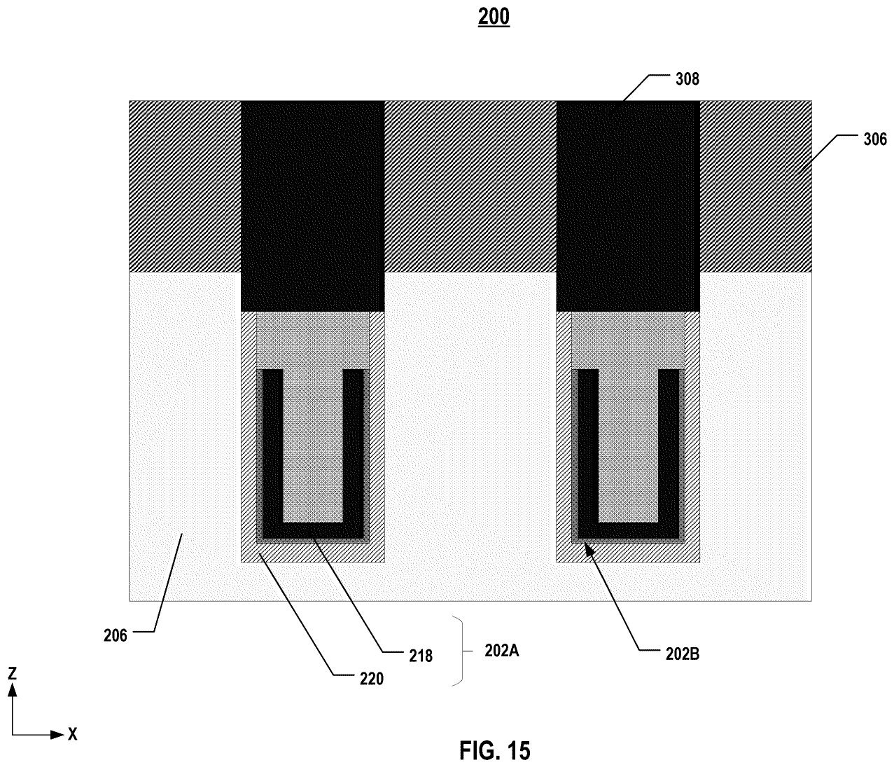

As shown in FIG. 15, gate structure 202 is formed in opening 304. In some implementations, gate structure 202 may include conductive layer 218 and gate dielectric layer 220. In some implementations, gate dielectric layer 220 is formed on the sidewalls of opening 201, and conductive layer 218 is formed on gate dielectric layer 220. In some implementations, conductive layer 218 may include tungsten (W), aluminum (Al), or other suitable material. In some implementations, conductive layer 218 may include multiple conductive layers, such as a W layer over a TiN layer. In some implementations, gate dielectric layer 220 can include any suitable dielectric materials, such as silicon oxide, silicon nitride, silicon oxynitride, or high-k dielectrics. For example, gate dielectric layer 220 may include silicon oxide, i.e., gate oxide. In some implementations, gate structure 202 extends in the Z-direction and the Y-direction.

As shown in FIG. 15, a sacrificial layer 308 is formed on gate structure 202. In some implementations, sacrificial layer 308 is formed in opening 304. In some implementations, sacrificial layer 308 may be a material suitable to be removed in a later operation. In some implementations, sacrificial layer 308 may be a tungsten (W) layer.

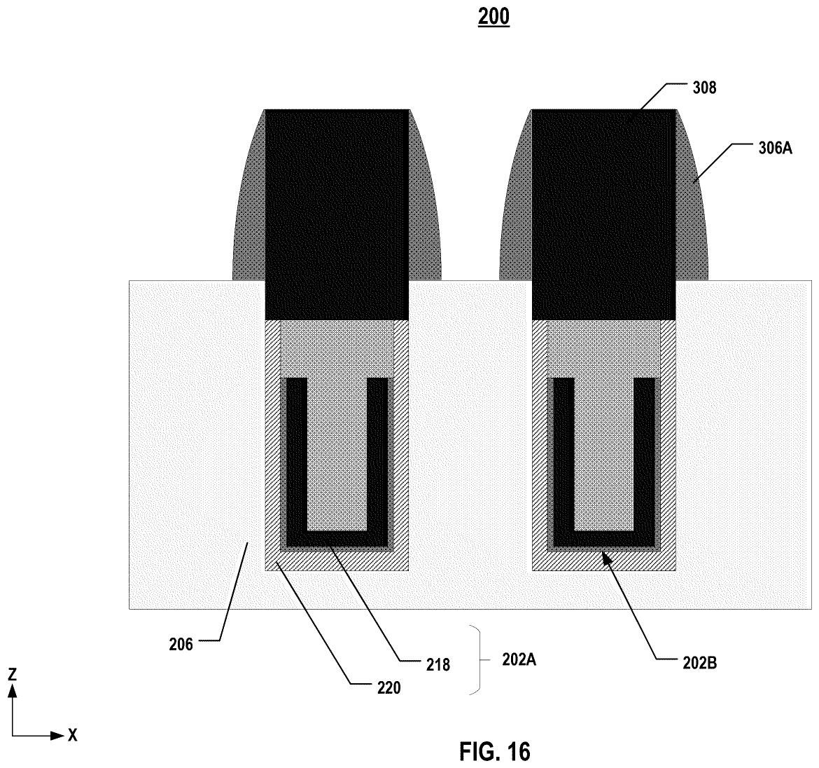

As shown in FIG. 16, a portion of mask layer 306 is removed to form a second mask layer 306A. In some implementations, a first portion of mask layer 306 is removed, and a second portion of mask layer 306 aside sacrificial layer 308 is retained to form second mask layer 306A. In some implementations, mask layer 306 may be removed by using dry etching process, wet etching process, or any suitable removal process.

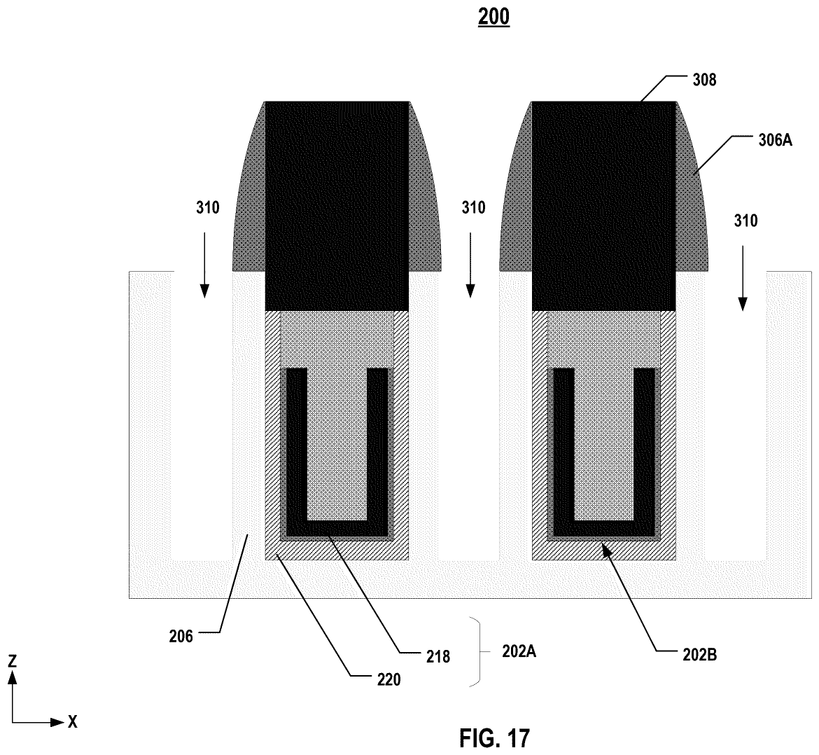

As shown in FIG. 17, an opening 310 is formed in dielectric material 206. In some implementations, opening 310 extends in the Z-direction and the Y-direction. In some implementations, sacrificial layer 308 and second mask layer 306A may be used as a mask when forming opening 310. In some implementations, the edge of opening 310 aligns with the edge of second mask layer 306A in the Z-direction.

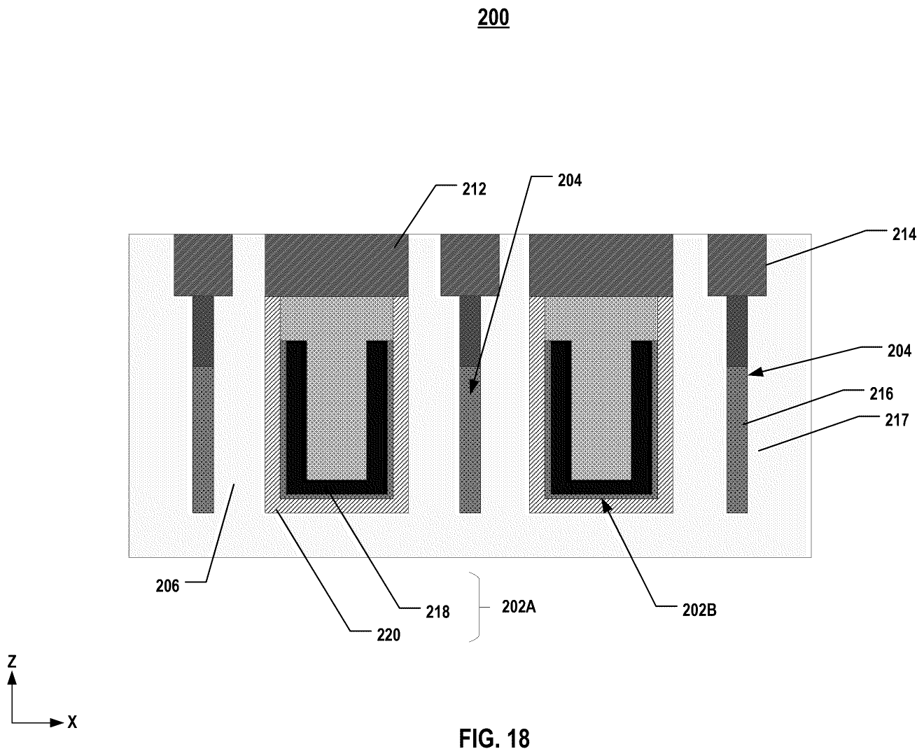

As shown in FIG. 18, isolation structure 204 is formed in opening 310, and sacrificial layer 308 is removed. In some implementations, isolation structure 204 may be formed by isolation core 216 covered by dielectric layer 217. In some implementations, the material of dielectric layer 217 may be the same as dielectric material 206. In some implementations, isolation structure 204 may be formed by forming an air gap in a dielectric material extending in the Z-direction. In some implementations, sacrificial layer 308 may be removed by using dry etching process, wet etching process, or any suitable removal process.

After removing sacrificial layer 308, dielectric layers 212 and 214 may be formed on gate structure 202 and isolation structure 204 aside second mask layer 306A. In some implementations, sacrificial layer 308 is removed to form an opening, and dielectric layer 212 is formed in the opening. In some implementations, dielectric layers 212 and 214 include silicon oxide or silicon nitride. Then, second mask layer 306A is removed.

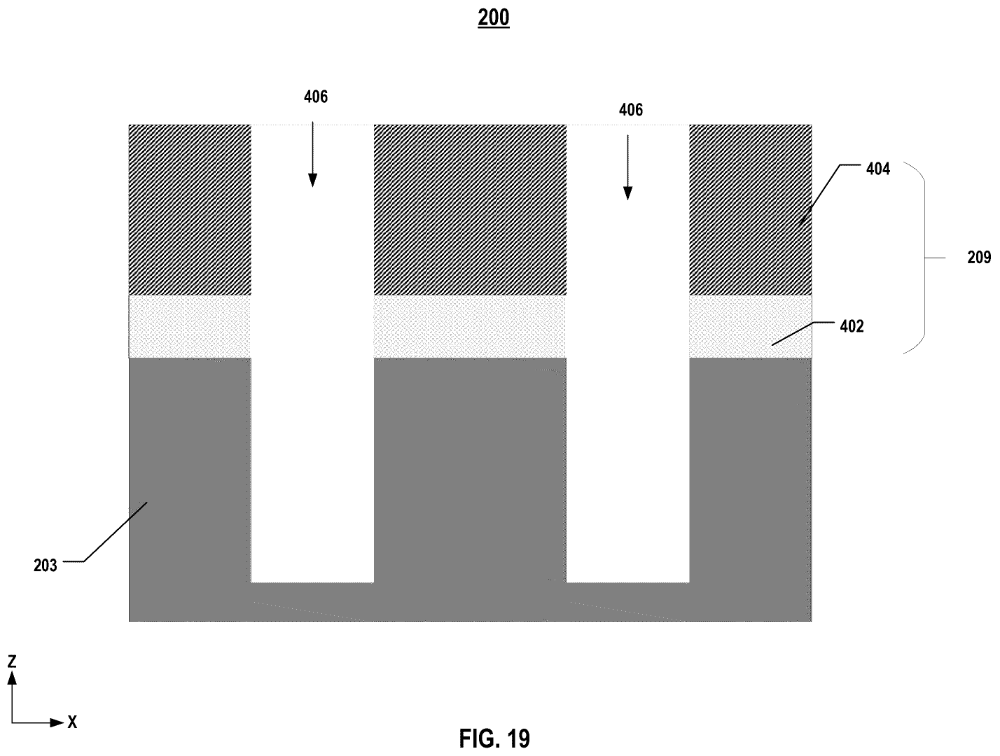

FIGS. 19-24 illustrate cross-sectional views of memory device 200 cut along line BB′ in FIG. 2 at various stages of a fabrication process, according to some implementations of the present disclosure.

As shown in FIG. 19, first mask layer 209 is formed on semiconductor body 203. In some implementations, first mask layer 209 may be a hard mask. In some implementations, first mask layer 209 may include a dielectric layer 402 and a dielectric layer 404. In some implementations, dielectric layer 402 may be a silicon oxide layer, and dielectric layer 404 may be a silicon nitride layer. Then, first mask layer 209 is patterned to form an opening on semiconductor body 203. Then, as shown in FIG. 19, an opening 406 is formed in semiconductor body 203 using first mask layer 209 as a mask. In some implementations, opening 406 extends in the Z-direction and the Y-direction. In some implementations, opening 406 may be formed by using dry etching process, wet etching process, or any suitable removal process.

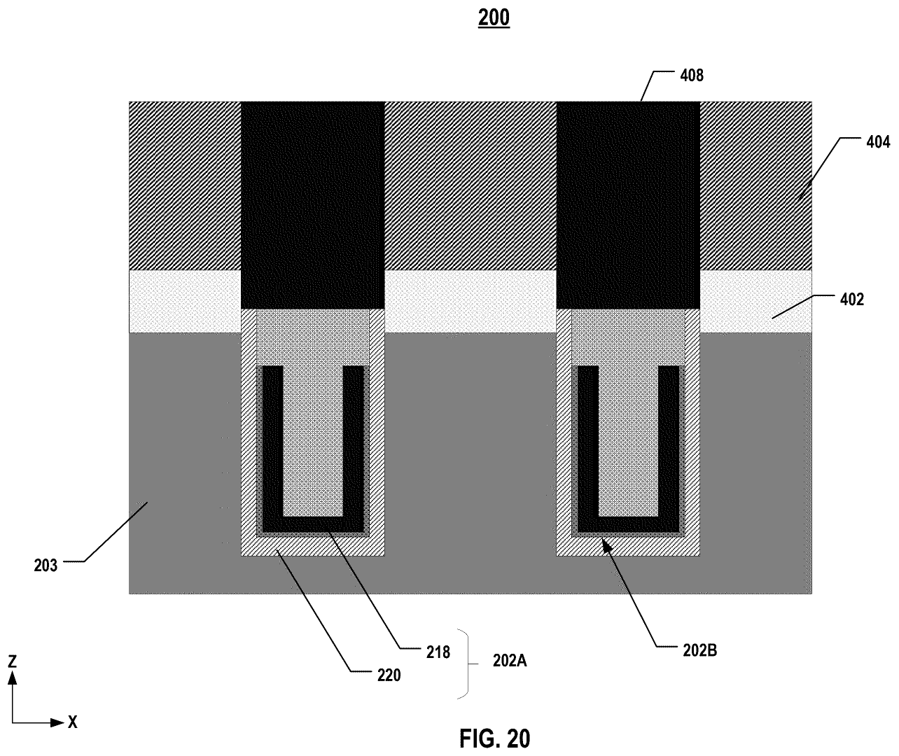

As shown in FIG. 20, gate structure 202 is formed in opening 406. In some implementations, gate structure 202 may include conductive layer 218 and gate dielectric layer 220. In some implementations, gate dielectric layer 220 is formed on the sidewalls of opening 201, and conductive layer 218 is formed on gate dielectric layer 220. In some implementations, conductive layer 218 may include tungsten (W), aluminum (Al), or other suitable material. In some implementations, conductive layer 218 may include multiple conductive layers, such as a W layer over a TiN layer. In some implementations, gate dielectric layer 220 can include any suitable dielectric materials, such as silicon oxide, silicon nitride, silicon oxynitride, or high-k dielectrics. For example, gate dielectric layer 220 may include silicon oxide, i.e., gate oxide. In some implementations, gate structure 202 extends in the Z-direction and the Y-direction. In some implementations, as shown in FIG. 20, the top surface of gate structure 202 may be above the top surface of semiconductor body 203 in the Z-direction. In some implementations, the top surface of gate structure 202 may be between the top surface and the bottom surface of dielectric layer 402 in the Z-direction.

As shown in FIG. 20, a sacrificial layer 408 is formed on gate structure 202. In some implementations, sacrificial layer 408 is formed in opening 406. In some implementations, sacrificial layer 408 may be a material suitable to be removed in a later operation. In some implementations, sacrificial layer 408 may be a tungsten (W) layer.

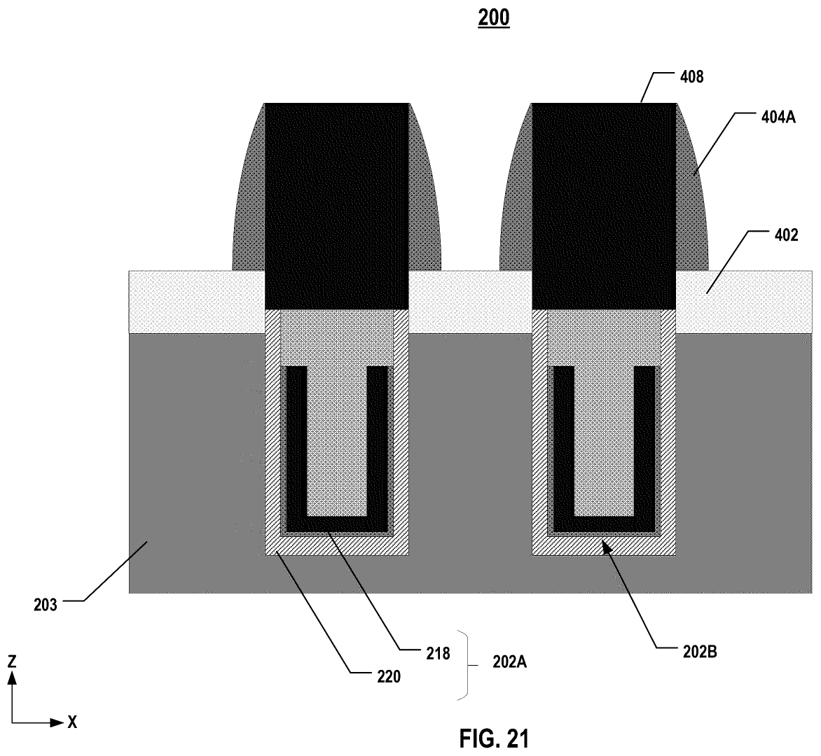

As shown in FIG. 21, a portion of dielectric layer 404 is removed to form a mask layer 404A. In some implementations, a first portion of dielectric layer 404 is removed, and a second portion of dielectric layer 404 aside sacrificial layer 408 is retained to form mask layer 404A. In some implementations, dielectric layer 404 may be removed by using dry etching process, wet etching process, or any suitable removal process.

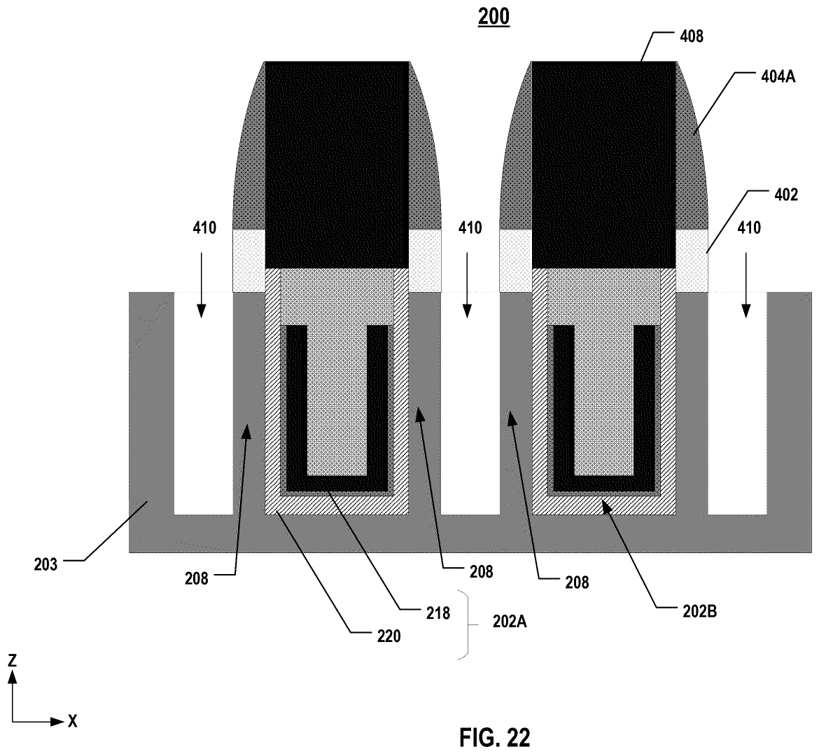

As shown in FIG. 22, an opening 410 is formed in semiconductor body 203 and dielectric layer 402. In some implementations, opening 410 extends in the Z-direction and the Y-direction. In some implementations, sacrificial layer 408 and mask layer 404A may be used as a mask when forming opening 410. In some implementations, the edge of opening 205 aligns with the edge of mask layer 404A in the Z-direction. After forming opening 410, semiconductor structure 208 is formed between opening 410 and gate structure 202. In some implementations, semiconductor structure 208 includes the same material as semiconductor body 203. In some implementations, semiconductor structure 208 extends in the Z-direction.

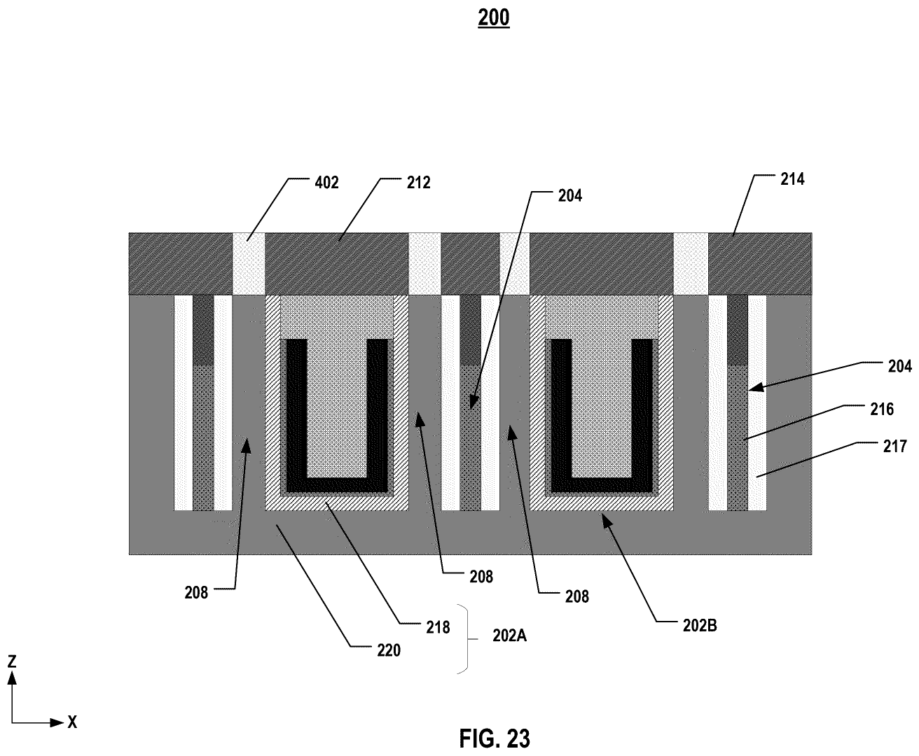

As shown in FIG. 23, isolation structure 204 is formed in opening 410, and sacrificial layer 408 is removed. In some implementations, isolation structure 204 may be formed by isolation core 216 covered by a dielectric layer 217. In some implementations, isolation structure 204 may be formed by forming an air gap in a dielectric material extending in the Z-direction. In some implementations, sacrificial layer 408 may be removed by using dry etching process, wet etching process, or any suitable removal process.

After removing sacrificial layer 207, dielectric layers 212 and 214 may be formed on gate structure 202 and isolation structure 204, aside dielectric layer 402 and mask layer 404A. In some implementations, mask layer 404A may be removed before forming dielectric layers 212 and 214 on gate structure 202 and isolation structure 204. In some implementations, mask layer 404A may be removed after forming dielectric layers 212 and 214 on gate structure 202 and isolation structure 204. In some implementations, sacrificial layer 408 is removed to form an opening, and dielectric layer 212 is formed in the opening. In some implementations, dielectric layers 212 and 214 include silicon oxide or silicon nitride.

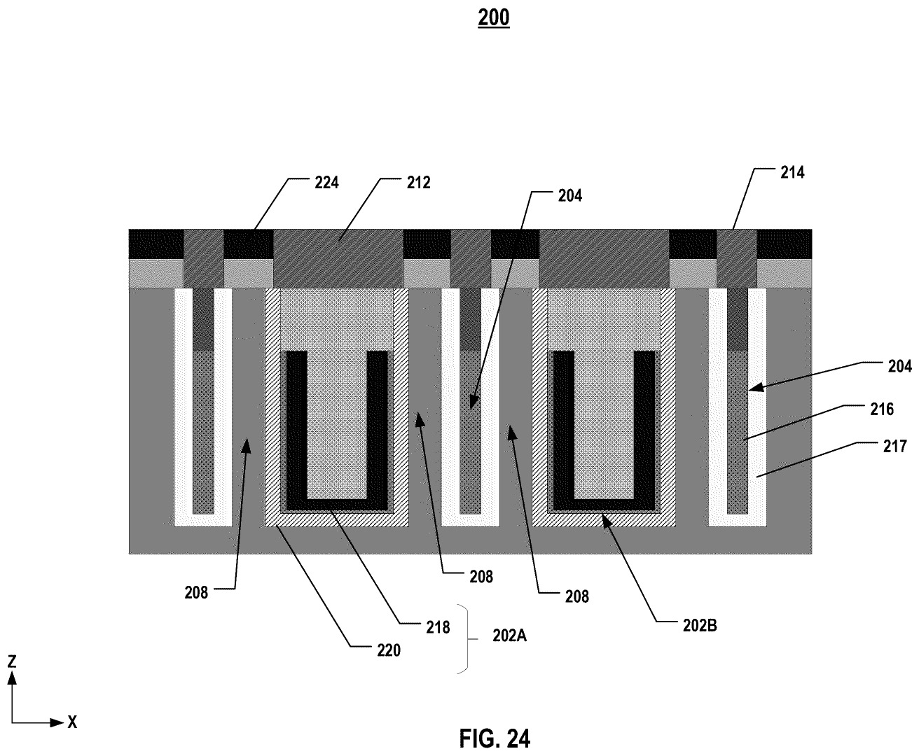

As shown in FIG. 24, dielectric layer 402 is removed to form an opening. In some implementations, dielectric layer 402 is removed to expose semiconductor structure 208. Then, contact structure 224 is formed in the opening. In some implementations, contact structure 224 is formed on the exposed semiconductor structure 208.

By using a hard mask, e.g., dielectric layer 402 and dielectric layer 404, to form a protection layer during the word line formation process, a portion of the hard mask could be retained as the self-alignment mask in the later trench formation process, e.g., opening 410 formation process. Hence, the contact, e.g., contact structure 224, can align with semiconductor structure 208, and the shifting problem can be prevented. The fabricating process can have a simplified source node contact (SNC) process, thereby reducing the product cost and increasing reliability.

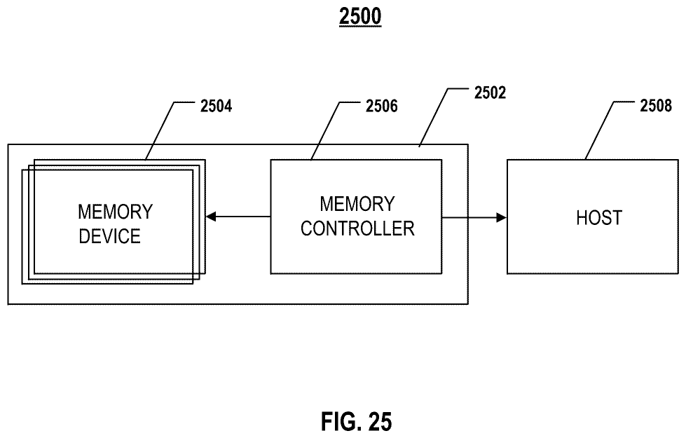

FIG. 25 illustrates a block diagram of a system 2500 having a memory device, according to some implementations of the present disclosure. System 2500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 25, system 2500 can include a host 2508 and a memory system 2502 having one or more memory devices 2504 and a memory controller 2506. Host 2508 can be a processor of an electronic device, such as a central processing unit (CPU), or a system-on-chip (SoC), such as an application processor (AP). Host 2508 can be configured to send or receive the data to or from memory devices 2504. Memory device 2504 can be any memory devices disclosed herein, such as memory device 200 discussed above.

Memory controller 2506 is coupled to memory device 2504 and host 2508 and is configured to control memory device 2504, according to some implementations. Memory controller 2506 can manage the data stored in memory device 2504 and communicate with host 2508. Memory controller 2506 can be configured to control operations of memory device 2504, such as read, write, and refresh operations. Memory controller 2506 can also be configured to manage various functions with respect to the data stored or to be stored in memory device 2504 including, but not limited to refresh and timing control, command/request translation, buffer and schedule, and power management. In some implementations, memory controller 2506 is further configured to determine the maximum memory capacity that the computer system can use, the number of memory banks, memory type and speed, memory particle data depth and data width, and other important parameters. Any other suitable functions may be performed by memory controller 2506 as well. Memory controller 2506 can communicate with an external device (e.g., host 2508) according to a particular communication protocol. For example, memory controller 2506 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A semiconductor device, comprising:
a first gate structure and a second gate structure extending in a first direction and a second direction perpendicular to the first direction;
a first isolation structure deposited between the first gate structure and the second gate structure extending in the first direction and the second direction;
a first semiconductor structure deposited between the first gate structure and the first isolation structure extending in the first direction;
a first contact structure deposited on the first semiconductor structure;
a first dielectric layer deposited on the first gate structure; and
a second dielectric layer deposited on the first isolation structure,
wherein the first contact structure comprises a first end in contact with the first semiconductor structure, a first center of the first end of the first contact structure in a third direction perpendicular to the first direction and the second direction aligns with a second center of the first semiconductor structure in the third direction.

2. The semiconductor device of claim 1, wherein the first center aligns with the second center in the first direction.

3. The semiconductor device of claim 1, wherein the first isolation structure comprises an isolation core and a third dielectric layer between the isolation core and the first semiconductor structure.

4. The semiconductor device of claim 1, wherein the first isolation structure comprises an air gap extending in the first direction.

5. The semiconductor device of claim 1, wherein the contact structure further comprises a second end away from the semiconductor structure, and a first width of the first end in the third direction is greater than a second width of the second end in the third direction.

6. The semiconductor device of claim 1, further comprising:
a second isolation structure, the first gate structure located between the first isolation structure and the second isolation structure;
a second semiconductor structure deposited between the first gate structure and the second isolation structure; and
a second contact structure deposited on the second semiconductor structure,
wherein each of the first contact structure and the second contact structure comprises a first inner edge close to the first gate structure and a first outer edge away from the first gate structure, each of the first isolation structure and the second isolation structure comprises a second inner edge close to the first gate structure and a second outer edge away from the first gate structure; and
a third center between the first outer edge of the first contact structure and the first outer edge of the second contact structure in the third direction aligns with a fourth center between the second inner edge of the first isolation structure and the second inner edge of the second isolation structure in the third direction.

7. The semiconductor device of claim 6, wherein the third center aligns with the fourth center along the first direction.

8. A semiconductor device, comprising:
a first isolation structure and a second isolation structure extending in a first direction and a second direction perpendicular to the first direction;
a gate structure deposited between the first isolation structure and the second isolation structure extending in the first direction and the second direction;
a first semiconductor structure deposited between the gate structure and the first isolation structure extending in the first direction;
a second semiconductor structure deposited between the gate structure and the second isolation structure extending in the first direction;
a first contact structure deposited on the first semiconductor structure, the first contact structure comprising a first inner edge close to the gate structure and a first outer edge away from the gate structure; and
a second contact structure deposited on the second semiconductor structure, the second contact structure comprising a second inner edge close to the gate structure and a second outer edge away from the gate structure,
wherein the first isolation structure comprises a first isolation core and a first dielectric layer between the first isolation core and the first semiconductor structure, the second isolation structure comprises a second isolation core and a second dielectric layer between the second isolation core and the second semiconductor structure; and
a first distance between the first outer edge of the first contact structure and an edge of the first dielectric layer in a third direction perpendicular to the first direction and the second direction is equal to a second distance between the second outer edge of the second contact structure and an edge of the second dielectric layer in the third direction.

9. The semiconductor device of claim 8, wherein each of the first isolation structure and the second isolation structure comprises an air gap extending in the first direction.

10. The semiconductor device of claim 8, further comprising:
a second dielectric layer deposited on the gate structure; and
a third dielectric layer deposited on the first isolation structure,
wherein a width of the second dielectric layer in the third direction is different from a width of the third dielectric layer in the third direction.

11. The semiconductor device of claim 8, further comprising:
a storage structure coupled with the semiconductor structure through the contact structure.

12. A method, comprising:
forming a first mask layer having a first opening on a semiconductor body;
forming a second opening in the semiconductor body extending in a first direction and a second direction perpendicular to the first direction;
forming a gate structure in the second opening;
removing a portion of the first mask layer to form a second mask layer;
removing a portion of the semiconductor body based on the second mask layer to form a semiconductor structure;
forming a first dielectric layer on the gate structure;
removing the second mask layer to form a third opening; and
forming a contact structure in the third opening.

13. The method of claim 12, wherein the semiconductor structure aligns with the contact structure in a third direction perpendicular to the first direction and the second direction.

14. The method of claim 12, wherein forming the second opening in the semiconductor body extending in the first direction and the second direction perpendicular to the first direction, comprises:
removing a portion of the semiconductor body under the first opening to form the second opening.

15. The method of claim 12, wherein forming the gate structure in the second opening, comprises:
forming a gate dielectric layer in the second opening; and
forming a gate electrode layer on the gate dielectric layer.

16. The method of claim 12, further comprising:
after forming the gate structure in the second opening, forming a sacrificial layer in the first opening.

17. The method of claim 16, wherein removing the portion of the first mask layer to form the second mask layer, comprises:
removing a first portion of the first mask layer and retaining a second portion of the first mask layer aside the sacrificial layer to form the second mask layer.

18. The method of claim 17, further comprising:
removing the sacrificial layer to form a fourth opening in the second mask layer.

19. The method of claim 18, wherein forming the first dielectric layer on the gate structure, comprises:
forming the first dielectric layer in the fourth opening.

20. The method of claim 12, wherein removing the second mask layer to form the third opening, comprises:
removing the second mask layer on the semiconductor body to expose the semiconductor body.
